(19) United States
(12) Patent Application Publication
(10) Pub. No.: US 2002/0017453 A1
(43) Pub. Date: Feb. 14, 2002

(54) Sputtering method and manufacturing method of semiconductor device using the same

(76) Inventor: Souichirou Iguchi, Shiga (JP)

Correspondence Address: MCGINN & GIBB, PLLC, 8321 OLD COURTHOUSE ROAD, SUITE 200, VIENNA, VA, 22182-3817, US

(21) Appl. No.: 09/813,158

(22) Filed: Mar. 21, 2001

(30) Foreign Application Priority Data
Mar. 22, 2000 (JP) 2000-084666

(51) Int. Cl. C23C 14/34; H01L 21/4763; H01L 21/44; H01L 21/311

(52) U.S. Cl. 204/192.17; 204/192.12; 438/648; 438/653; 438/656; 438/685; 438/696; 438/703

(57) ABSTRACT

A first Ti film is formed by sputtering with the space between a semiconductor substrate and a target provided at a greater distance such as 350 mm, subsequently, a second Ti film is formed again by sputtering with a shorter distance such as 80 mm, thereon a first TiN film is formed by sputtering with a greater distance such as 350 mm, and, subsequently, a second TiN film is formed again by sputtering with a shorter distance such as 80 mm. Then, these first and second Ti films and first and second TiN films are combined to provide a barrier layer.

### BACKGROUND OF THE INVENTION

1. Technical Field of the Invention

The present invention relates to a sputtering method for forming a film in a contact through hole which connects a conductive region of an element formed on a semiconductor substrate and wiring and a through hole (hereinafter, generally referred to as a through hole) which connects lower wiring and upper wiring and a manufacturing method of a semiconductor device using the sputtering method, and relates to, in particular, a sputtering method preferable to connect by a contact through hole having a large aspect ratio and a manufacturing method for a semiconductor device using the same.

2. Description of the Related Art

As to a wiring structure of a semiconductor device, connection between lower wiring (including an active region of an element formed on a semiconductor substrate) and upper wiring above it is often carried out by providing a through hole provided in an interlayer insulation film between the lower wiring and upper wiring. A prior-art manufacturing method with such a wiring structure will be explained. FIG. 1A through FIG. 1E are sections showing steps by a manufacturing method of a conventional wiring structure in order.

As shown in FIG. 1A, lower wiring 2 extending in the direction vertical to the drawing is formed by a material containing Aluminum (Al) as the main component on the surface of a semiconductor substrate 1 with an insulation film (not illustrated) formed on the surface thereof. An insulation film is formed on the surface of the semiconductor substrate 1 and lower wiring 2, for example, by a CVD method and the film is processed by flattening to become an interlayer insulation film 3. Then, a through hole 4 is made at a predetermined position of the interlayer insulation film 3 by anisotropic dry etching. In this case, the through hole 4 has a diameter of, for example, approximately 0.8 μm and an aspect ratio of approximately 1.

Then, as shown in FIG. 1B, a barrier layer 5 such as a laminated film (Ti/TiN laminated film) comprising, for example, a titanium film (hereinafter, referred to as a Ti film) and a titanium nitride film is formed by the sputtering method so that the surface of the interlayer insulation film 3 and the side surface and bottom surface of the through hole 4 are covered. The space between the semiconductor substrate 1 and a target (not illustrated) when the barrier layer 5 is deposited is, for example, 80 mm in either case of the Ti film and TiN film.

Then, as shown in FIG. 1C, a tungsten film (hereinafter, referred to as a W film) 6 is formed to become of a thickness that fills the through hole 4 on the whole surface of the semiconductor substrate 1 by the CVD method.

Then, as shown in FIG. 1D, the whole surface of the W film is etched back until the surface of the barrier layer 5 is exposed and a tungsten plug (hereinafter, referred to as a W plug) 7 is formed with a part of the W film remaining in the through hole 4.

Then, as shown in FIG. 1E, a film made of a material containing Al as the main component is formed on the whole surface of the semiconductor substrate 1 by the sputtering method, the film of the material and the barrier layer 5 are patterned, and upper wiring 8 extending rightward and leftward in FIG. 1E is formed so as to be connected to the lower wiring 2 via the W plug 7 and barrier layer 5.

Thus, the contact hole or through hole is filled by the W plug by means of a blanket method, therefore, even by means of the contact hole or through hole having a relatively large aspect ratio, the upper and lower wiring can be connected.

Herein, when the barrier layer 5 is deposited by the sputtering method, particles (film components) flying toward the through hole 4 to become the barrier layer 5 contain a component which arrives by flying from a portion right above the through hole 4 of a material target and is perpendicular to the semiconductor substrate 1 and a component which arrives by flying from the other portion and is inclined. FIG. 2A is a section showing a deposited condition in a case where the distance between the semiconductor substrate and a target is close, while FIG. 2B is a section showing a deposited condition in a case where the distance between the semiconductor substrate and a target is far. When the distance between the semiconductor substrate and target is close, as shown in the section of FIG. 2A, though the deposition speed at a flat surface portion 9 accelerates, the inclined component increases and the ratio of the component which reaches a bottom surface 10 of the through hole decreases. Accordingly, the barrier layer 5 thus deposited is thinner at the bottom surface 10 of the through hole than at the flat surface portion 9. Then, the barrier layer 5 tends to be thinner when it is closer to the bottom surface 10 on a side surface 11 of the through hole. On the other hand, when the distance between the target and semiconductor substrate 1 is sufficiently far, as shown in the section of FIG. 2B, the deposition speed decelerates at the flat surface portion 9, the inclined component decreases, and the ratio of the component which reaches the bottom surface 10 of the through hole increases. Accordingly, though the tendency for the barrier layer 5 thus deposited to be thinner at the bottom surface 10 of the through hole than at the flat surface portion 9 remains, the difference decreases. And, though the tendency for the barrier layer 5 to be thinner when it is closer to the bottom surface 10 on the side surface 11 of the through hole remains, the difference thereof between the upper opening side and bottom surface side decreases and the barrier layer 5 is, as a whole, thinner than that at the flat surface portion 9.

Therefore, for example, when the diameter of the through hole becomes 0.5 μm and the aspect ratio becomes approximately 1.5, if the space between the semiconductor substrate 1 and target is approximately 80 mm as in the abovementioned example, in order to deposit a film with a predetermined thickness on the bottom surface 10 of the through hole, the film becomes thick on the upper opening side of the side surface 11 and it clogs the opening in an eaves-like manner, and the following formation of the W plug 7 becomes inconvenient. Therefore, for example, by providing an approximately 300 mm space between the semiconductor substrate 1 and target, the difference in film thickness of the barrier layer 5 in the depth direction of the side surface 11 of the through hole is reduced. Thus, although the deposition speed decelerates, the predetermined film thickness can be provided on the bottom surface 10 of the through hole.

However, when the contact hole or through hole becomes still smaller and, for example, the diameter of the contact hole or through hole becomes 0.4 μm or less and the aspect ratio becomes approximately 2, even if the film thickness on the bottom surface of the contact hole or through hole is intended to be secured by providing further space between the semiconductor substrate and the target, the film thickness on the side surface cannot be secured since the component, which arrives by flying in the inclined direction, is reduced, and there provides a problem such that a connection resistance between the lower wiring and upper wiring increases in a case where the upper wiring is formed by filling the W plug in the hole.

### SUMMARY OF THE INVENTION

The object of the present invent invention is to provide a sputtering method whereby a film can be deposited more uniformly on the side surface and bottom surface of a contact hole or a through hole having a large aspect ratio and a minimum necessary film thickness can be easily secured even at a thin section thereof and a manufacturing method of a semiconductor device using the same sputtering method.

The sputtering method according to the present invention is a sputtering method for depositing a film on the surface of a substrate and the side surface and bottom surface of a concave portion provided at the substrate. A first film is formed by sputtering with the space between the substrate and a sputtering target as a first distance and, subsequently, a second film which is made of the same material with the first film is formed by sputtering with the space between the substrate and the target as a second distance which is different from the first distance.

One of said first distance and second distance is a distance which is larger than the other one and allows easy accumulation on the bottom surface of the concave portion. The other distance is a distance which allows easy accumulation on the side surface of the concave portion.

In the present invention, the first distance and the second distance are combined and, in part of the process of sputtering, deposition is performed under conditions where accumulation easily occurs on the bottom surface of the concave portion and, in the rest of the process, deposition is performed under conditions where accumulation easily occurs on the side surface of the concave portion. Hereby, a film with a most preferable film thickness can be deposited both on the bottom surface and side surface of the concave portion. That is, according to the sputtering method of the present invention, a minimum necessary film thickness can be secured all over the side surface of the concave portion of the substrate provided with the concave portion having a large aspect ratio, the bottom surface of the concave portion, and the surface of the substrate.

In addition, according to the sputtering method, deposition can effectively be performed by first employing either of the first distance and the second distance, however, in order to perform deposition on a concave portion with an especially large aspect ratio, it is preferable to perform sputtering by making the first distance relatively far to secure a necessary film thickness on the bottom surface of the concave portion while preventing the opening of the concave portion from becoming too narrow, and thereafter to accumulate a necessary film thickness on the side surface of the concave portion by making the second distance relatively close.

The abovementioned sputtering method is preferable to form, on the surface of a semiconductor substrate on which lower wiring is formed, an interlayer insulation film provided with a through hole which exposes a predetermined position of the lower wiring, and to deposit a conductive material on the surface of the interlayer film and the side surface and bottom surface of the through hole. In particular, it is preferable to deposit a layer having a relatively thin film thickness such as a barrier layer made of the conductive material.

Herein, in the present invention, reference to “lower wiring” includes an impurities dispersion region formed on the semiconductor substrate. A hole which connects between a conductive region such as the impurities dispersion region and the like on the semiconductor substrate and wiring on the insulation film thereon and which is provided in the insulation film is generally referred to as a contact hole, however, in the present invention, simple reference to “through hole” includes “contact hole”.

The manufacturing method of a semiconductor device according to the present invention comprises the steps of:

forming an insulation film on a conductive region formed on the surface of a semiconductor substrate or on the lower wiring formed on the semiconductor substrate,

forming a contact hole or a through hole on the insulation film, and

depositing a conductive material on the surface of the insulation film and the side surface and bottom surface of the contact hole or through hole by the abovementioned sputtering method of the present invention.

Another manufacturing method of a semiconductor device according to the present invention comprises the steps of:

forming an insulation film on a conductive region formed on the surface of a semiconductor substrate or on the lower wiring formed on the semiconductor substrate,

forming a contact hole or a through hole on the insulation film, forming a barrier layer on the surface of the insulation film and the side surface and bottom surface of the contact hole or through hole by the abovementioned sputtering method of the present invention, and

forming, subsequently, a tungsten plug in the contact hole or through hole.

According to the manufacturing method of a semiconductor device of the present invention to which the sputtering method of the present invention is applied, even though the aspect ratio of the contact hole which connects between the conductive region of the element formed on the semiconductor substrate and wiring or the through hole which connects between the lower wiring and upper wiring is large, since the barrier layer can be formed at a minimum necessary thickness on the side surface and bottom surface of the contact hole or through hole, connection between the lower wiring and upper wiring can securely be performed.

### BRIEF DESCRIPTION OF THE DRAWINGS

FIG. 1A through FIG. 1E are sections showing processes by a manufacturing method of a conventional wiring structure in order.

FIG. 2A is a section showing a deposited condition in a case where the distance between the semiconductor substrate and target is close, while FIG. 2B is a section showing a deposited condition in a case where the distance between the semiconductor substrate and target is far.

FIG. 3A through FIG. 3G are sections showing processes by a manufacturing method of a semiconductor device according to an embodiment of the present invention in order.

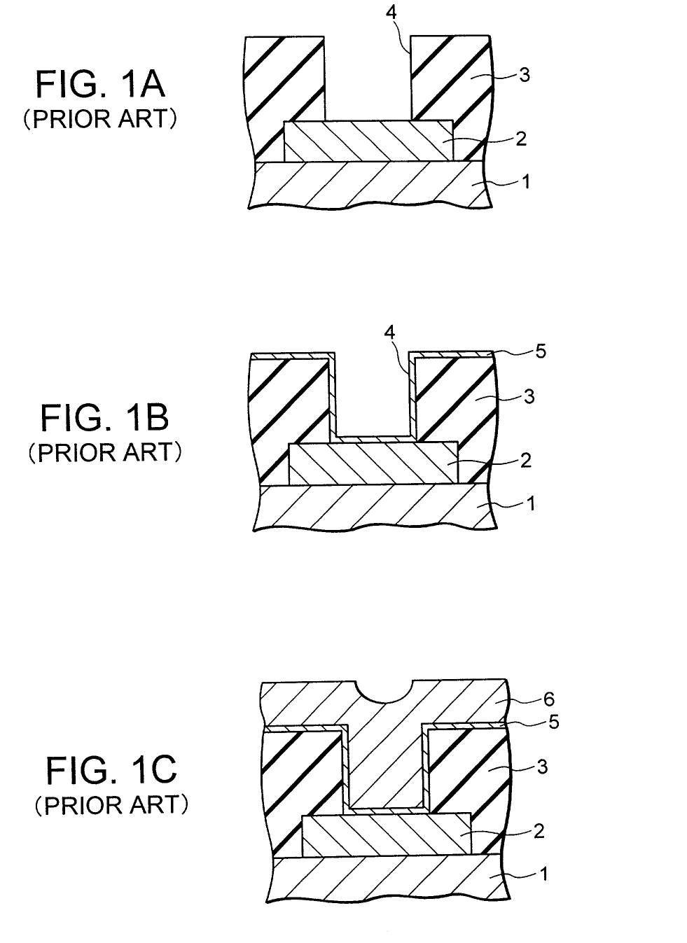

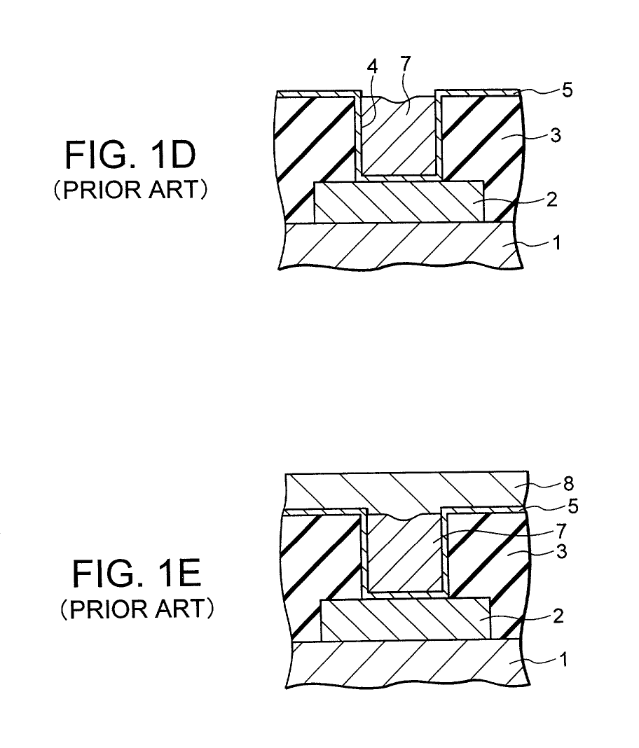

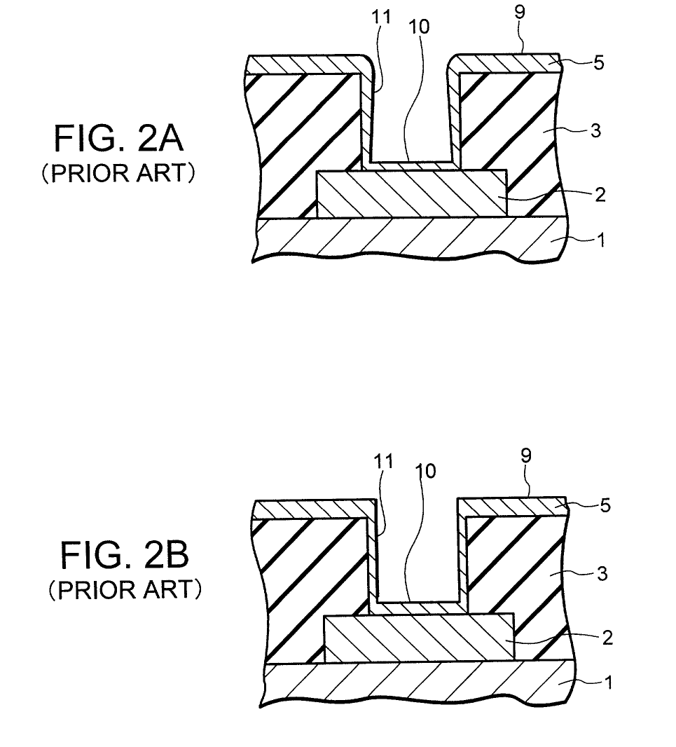

### DETAILED DESCRIPTION OF THE PREFERRED EMBODIMENTS

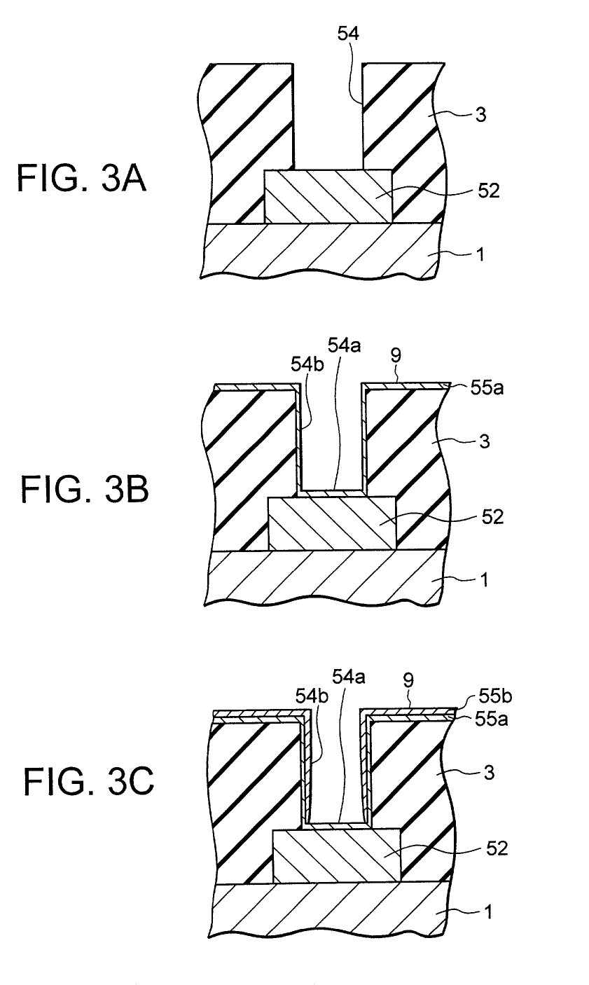

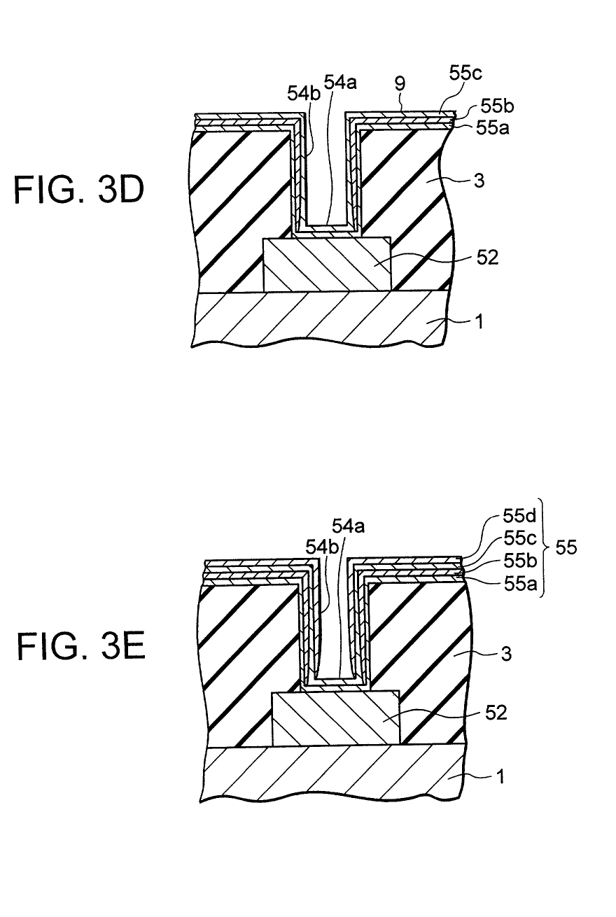

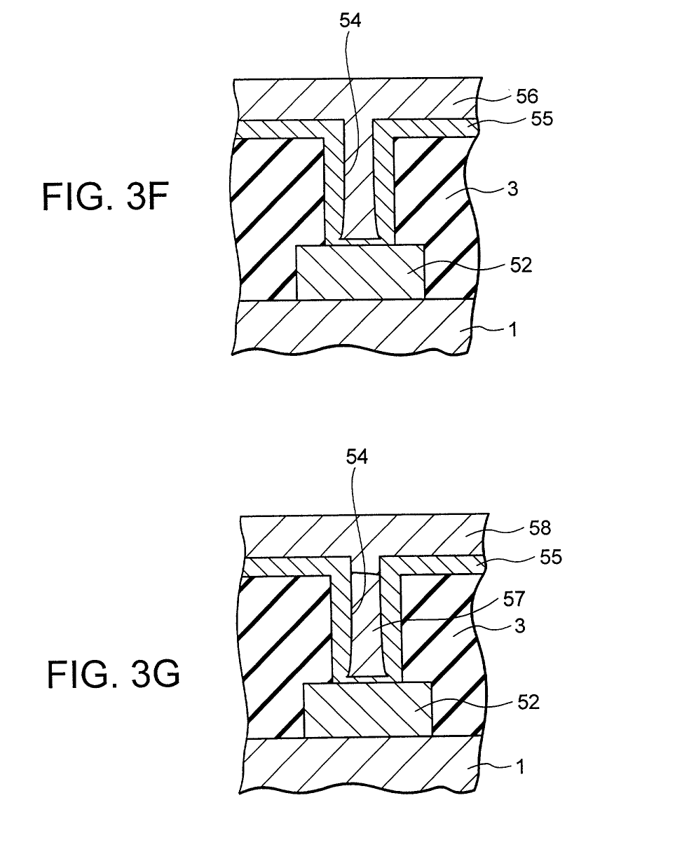

Hereinafter, a preferred embodiment of the present invention will be described in detail with reference to drawings hereto attached. FIG. 3A through FIG. 3G are sections showing processes by a manufacturing method of a semiconductor device according to the embodiment of the present invention in order.

First, an insulation film (not illustrated) is formed on the surface of a semiconductor layer 1. Then, as shown in FIG. 3A, lower wiring 52 extending in the direction vertical to the drawing is formed by a material containing, for example, Aluminum (Al) as the main component on the surface of the insulation film. On the surface of the semiconductor substrate 1 and lower wiring 52, an insulating film such as a PSG (phosphorous silicate glass) is formed, for example, by a CVD (chemical vapor deposition) method and the film is processed by flattening to become an interlayer insulation film 3. Then, a through hole 54 is made at a predetermined position of the interlayer insulation film 3 by anisotropic dry etching so that the lower wiring 52 is exposed. In this case, the through hole 54 has a diameter of, for example, approximately 0.4 μm and an aspect ratio of approximately 1.6.

As shown in FIG. 3B, for example, a first Ti film 55a is then formed by a sputtering method with the space between the semiconductor substrate 1 and a target (not illustrated) provided as, for example, 350 mm (a first distance) so that the surface of the interlayer insulation film 3 and a side surface 54b and a bottom surface 54a of the through hole are covered. In this case, accumulation occurs relatively easily on a flat surface portion 9 of the interlayer insulation film 3 and the bottom surface 54a of the through hole, whereas accumulation on the side surface 54b of the through hole is small.

Then, as shown in FIG. 3C, a second Ti film 55b is formed by a sputtering method with the space between the semiconductor substrate 1 and a target (not illustrated) provided as, for example, 80 mm (a second distance) so that the first Ti film 55a is covered. In this case, accumulation occurs relatively easily on the flat surface portion 9 and the side surface 54b of the through hole, whereas accumulation on the side surface 54b of the through hole is thicker on the upper opening side and it is thinner on the bottom surface side. The sputtering method of the present invention is a method whereby a necessary film thickness is secured on the side surface 54b and bottom surface 54a of the through hole by combining the first Ti layer 55a and the second Ti layer 55b.

Then, as shown in FIG. 3D, for example, a first TiN film 55c is formed by a sputtering method with the space between the semiconductor substrate 1 and a target (not illustrated) provided as, for example, 350 mm (a first distance) so that the second Ti film 55b is covered. In this case, accumulation occurs relatively easily on the flat surface portion 9 and the bottom surface 54a of the through hole, whereas accumulation on the side surface 54b of the through hole is small.

Then, as shown in FIG. 3E, a second TiN film 55d is formed by a sputtering method with the space between the semiconductor substrate 1 and a target (not illustrated) provided as, for example, 80 mm (a second distance) so that the first TiN film 55c is covered. In this case, accumulation occurs relatively easily on the flat surface portion 9 and the side surface 54b of the through hole, whereas accumulation on the side surface 54b of the through hole is thicker on the upper opening side and it is thinner on the bottom surface side. Thus, the sputtering method of the present invention is a method whereby a necessary film thickness is secured on the side surface 54a and bottom surface 54b of the through hole by combining the first TiN layer 55c and the second TiN layer 55d. Furthermore, the first Ti layer 55a, the second Ti layer 55b, the first TiN layer 55c, and the second TiN layer 55d are combined and used as a barrier 55.

Then, as shown in FIG. 3F, a W film 56 is formed to become of a thickness that fills the through hole 54 on the whole surface of the semiconductor substrate 1 by the CVD method.

Then, as shown in FIG. 3G, the whole surface of the W film is etched back until the surface of the barrier layer 55 is exposed and a W plug 57 is formed with a part of the W film remaining in the through hole 54. Then, a film made of a material containing Al as the main component is formed on the whole surface of the semiconductor substrate 1 by a sputtering method, the film of the material and the barrier layer 55 are patterned, and an upper wiring 58 extending rightward and leftward in FIG. 3G is formed. The upper wiring 58 is formed so as to be connected to the lower wiring 52 via the W plug 57 and barrier layer 55.

According to the abovementioned manufacturing method, such a sputtering method of the present invention is separately applied to the Ti films and TiN films composing the barrier layer 55, such that the first Ti film 55a and the first TiN film 55c are deposited with the space between the semiconductor substrate 1 (substrate) and target provided as 350 mm (the first distance), and, subsequently, the second Ti film 55b and the second TiN film 55d are deposited with the space between the semiconductor substrate 1 (substrate) and target provided as 80 mm (the second distance), and, therefore, a minimum necessary film thickness can be secured on all portions by the sputtering method for depositing a film on the flat surface 9 of the substrate provided with the through hole 54 (concave portion) and the side surface 54b and bottom surface 54a of the through hole.

In the abovementioned embodiment, a case where the lower wiring and upper wiring in the present invention are respectively metal wiring made of Al as the main component is described, however, the present invention can also be applied to a case, in a similar manner, where the lower wiring is an active region (impurities introduction region) of the semiconductor substrate and the upper wiring is, for example, first layer metal wiring. Furthermore, it is needless to say that another wiring irrelevant to the connection structure of the present invention may be included in the interlayer insulation film 3 of the present invention.

What is claimed is:

1. A sputtering method for depositing a film on the surface of a substrate and on the side surface and bottom surface of a concave portion provided at said substrate, comprising the steps of:
forming a first film by sputtering with the space between said substrate and a sputtering target as a first distance; and
forming, subsequently, a second film made of the same material with said first film by sputtering with the space between said substrate and said target as a second distance different from said first distance, one of said first and second distances being a distance which is larger than the other distance, and the larger one being a distance which allows easy accumulation on the bottom surface of said concave portion and the shorter one being a distance which allows easy accumulation on the side surface of said concave portion.

2. A sputtering method according to claim 1, wherein said first distance is larger than said second distance.

3. A manufacturing method of a semiconductor device comprising the steps of:
forming an insulation film on a conductive region formed at the surface of a semiconductor substrate or on a lower wiring formed on the semiconductor substrate,
forming a contact hole or a through hole at said insulation film, and
forming a conductive material on the surface of said insulation film and on the side surface and bottom surface of said contact hole or through hole by the sputtering method according to claim 1 or 2.

4. A manufacturing method of a semiconductor device comprising the steps of:
forming an insulation film on a conductive region formed at the surface of a semiconductor substrate or on lower wiring formed on the semiconductor substrate,
forming a contact hole or a through hole at said insulation film,
forming a barrier layer on the surface of said insulation film and on the side surface and bottom surface of said contact hole or through hole by the sputtering method according to claim 1 or 2, and
forming thereafter a tungsten plug in said contact hole or through hole.
